(19) United States
(12) Patent Application Publication
(10) Pub. No.: US 2025/0330131 A1
(43) Pub. Date: Oct. 23, 2025

(54) BANDWIDTH EXTENSION FOR A VOLTAGE BUFFER

(71) Applicant: QUALCOMM Incorporated, San Diego, CA (US)

(72) Inventors: Yongjian TANG, San Diego, CA (US); Kenneth Luis ARCUDIA, Cary, NC (US)

(21) Appl. No.: 18/643,131

(22) Filed: Apr. 23, 2024

(51) Int. Cl. H03F 1/42; H03F 3/45

(52) U.S. Cl. CPC H03F 1/42; H03F 3/45475

(57) ABSTRACT

In certain aspects, a voltage buffer includes a first source follower having an input and an output, and a second source follower having an input and an output. The voltage buffer also includes a first transistor, wherein a drain of the first transistor is coupled to the output of the first source follower, and a first coupling capacitor coupled between a gate of the first transistor and the input of the second source follower. The voltage buffer also includes a second transistor, wherein a drain of the second transistor is coupled to the output of the second source follower, and a second coupling capacitor coupled between a gate of the second transistor and the input of the first source follower. The voltage buffer further includes a current source coupled to a source of the first transistor and a source of the second transistor.

### BACKGROUND

### Field

Aspects of the present disclosure relate generally to voltage buffers, and more particularly, to bandwidth extension for a voltage buffer.

### Background

A system may include a voltage buffer for driving a circuit with a capacitive load based on an input signal. The circuit may include an analog-to-digital converter (ADC) or another type of circuit. A voltage buffer may include one or more source followers.

### SUMMARY

The following presents a simplified summary of one or more implementations in order to provide a basic understanding of such implementations. This summary is not an extensive overview of all contemplated implementations and is intended to neither identify key or critical elements of all implementations nor delineate the scope of any or all implementations. Its sole purpose is to present some concepts of one or more implementations in a simplified form as a prelude to the more detailed description that is presented later.

A first aspect relates to a voltage buffer. The voltage buffer includes a first transistor, wherein a gate of the first transistor is coupled to a first input of the voltage buffer, and a source of the first transistor is coupled to a first output of the voltage buffer. The voltage buffer also includes a second transistor, wherein a gate of the second transistor is coupled to a second input of the voltage buffer, and a source of the second transistor is coupled to a second output of the voltage buffer. The voltage buffer also includes a first current source coupled to the source of the first transistor and a second current source coupled to the source of the second transistor. The voltage buffer also includes a third transistor, wherein a drain of the third transistor is coupled to the source of the first transistor, and a first coupling capacitor coupled between a gate of the third transistor and the second input of the voltage buffer. The voltage buffer also includes a fourth transistor, wherein a drain of the fourth transistor is coupled to the source of the second transistor, and a second coupling capacitor coupled between a gate of the fourth transistor and the first input of the voltage buffer. The voltage buffer further includes a third current source coupled to a source of the third transistor and a source of the fourth transistor.

A second aspect relates to a voltage buffer. The voltage buffer includes a first source follower having an input and an output, and a second source follower having an input and an output. The voltage buffer also includes a first transistor, wherein a drain of the first transistor is coupled to the output of the first source follower, and a first coupling capacitor coupled between a gate of the first transistor and the input of the second source follower. The voltage buffer also includes a second transistor, wherein a drain of the second transistor is coupled to the output of the second source follower, and a second coupling capacitor coupled between a gate of the second transistor and the input of the first source follower. The voltage buffer further includes a current source coupled to a source of the first transistor and a source of the second transistor.

A third aspect relates to a method for operating a voltage buffer. The voltage buffer includes a first source follower and a second source follower. The method includes receiving a first input voltage and a second input voltage, steering a current of a current source to the first source follower during a first time period in which the second input voltage is greater than the first input voltage, and steering the current of the current source to the second source follower during a second time period in which the first input voltage is greater than the second input voltage.

### BRIEF DESCRIPTION OF THE DRAWINGS

FIG. 1 shows an example of a voltage buffer including a first source follower and a second source follower according to certain aspects of the present disclosure.

FIG. 2 shows an example of a voltage buffer with bandwidth extension according to certain aspects of the present disclosure.

FIG. 3 shows an exemplary implementation of current sources in the voltage buffer of FIG. 2 according to certain aspects of the present disclosure.

FIG. 4 shows an example in which the voltage buffer of FIG. 2 includes programmable current sources according to certain aspects of the present disclosure.

FIG. 5 shows an example of a voltage buffer including p-type field effect transistors (PFETs) according to certain aspects of the present disclosure.

FIG. 6 shows an example of a system including a voltage buffer according to certain aspects of the present disclosure.

FIG. 7 is a flowchart illustrating a method of operating a voltage buffer according to certain aspects of the present disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

A voltage buffer may be used in a high-speed system to drive a circuit with a capacitive load such as an analog-to-digital converter (ADC) or another circuit. The bandwidth and drivability of the voltage buffer are important as they determine the signal quality for subsequent stages in the system.

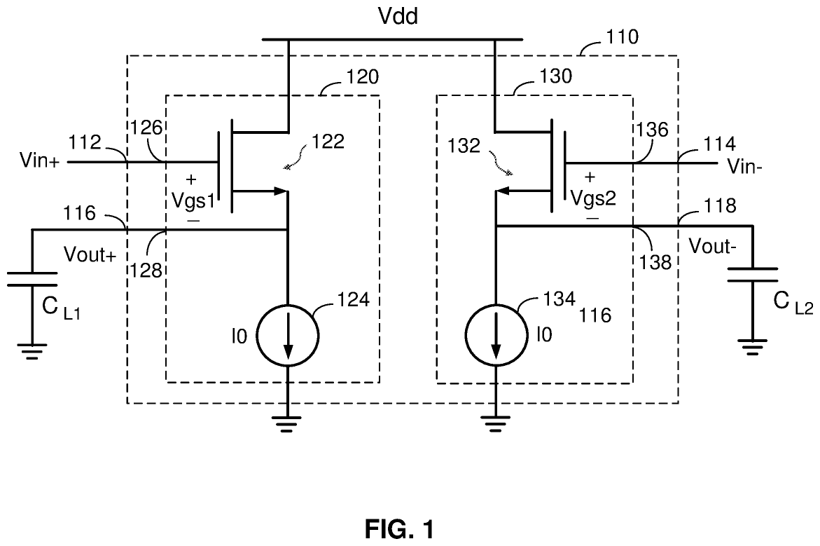

A voltage buffer may include one or more source followers. In this regard, FIG. 1 shows an example of a differential voltage buffer 110 including a first source follower 120 and a second source follower 130 according to certain aspects. A source follower may also be referred to as a common-drain amplifier.

In this example, the voltage buffer 110 has a first input 112, a second input 114, a first output 116, and a second output 118. The voltage buffer 110 is configured to receive a differential signal including a first signal input to the first input 112 and a second signal input to the second input 114. The first signal has a first input voltage Vin+ and the second signal has a second input voltage Vin−. In the example shown in FIG. 1, the first output 116 is coupled to a first capacitive load C_{L1} and the second output 118 is coupled to a second capacitor load C_{L2}. The capacitive loads C_{L1} and C_{L2} may represent the input capacitances of a circuit (e.g., ADC) driven by the voltage buffer 110.

The first source follower 120 includes a first transistor 122 and a first current source 124. The gate of the first transistor 122 (e.g., an n-type field effect transistor (NFET)) is coupled to an input 126 of the first source follower 120, the drain of the first transistor 122 is coupled to a supply rail having a supply voltage Vdd, and the source of the first transistor 122 is coupled to an output 128 of the first source follower 120. The first current source 124 is coupled between the source of the first transistor 122 and ground. The first current source 124 is configured to provide a bias current I0. In the example shown in FIG. 1, the first input 112 of the voltage buffer 110 is coupled to the input 126 of the first source follower 120 and the first output 116 of the voltage buffer 110 is coupled to the output 128 of the first source follower 120.

The first input voltage Vin+ at the first input 112 of the voltage buffer 110 is input to the input 126 of the first source follower 120. The first source follower 120 has a voltage gain of approximately one, in which a first output voltage Vout+ at the output 126 of the first source follower 120 (which is coupled the first output 116 of the voltage buffer 110) is approximately equal to the first input voltage Vin+ minus the gate-to-source voltage Vgs1 of the first transistor 122. Thus, the first output voltage Vout+ tracks the first input voltage Vin+ where the first output voltage Vout+ is shifted down from the first input voltage Vin+ by Vgs1. When the first input voltage Vin+ increases, the first source follower 120 sources current from the supply rail to the first load capacitor C_{L1} through the first transistor 122. The sourced current charges the first load capacitor C_{L1} which increases the first output voltage Vout+ to track the increase in the first input voltage Vin+. When the first input voltage Vin+ decreases, the first current source 124 sinks current from the first load capacitor C_{L1}. The sunk current discharges the first load capacitor C_{L1} which decreases the first output voltage Vout+ to track the decrease in the first input voltage Vin+.

The second source follower 130 includes a second transistor 132 and a second current source 134. The gate of the second transistor 132 (e.g., an NFET) is coupled to an input 136 of the second source follower 130, the drain of the second transistor 132 is coupled to the supply rail, and the source of the second transistor 132 is coupled to an output 138 of the second source follower 130. The second current source 134 is coupled between the source of the second transistor 132 and ground. The second current source 134 is configured to provide the bias current I0. In the example shown in FIG. 1, the second input 114 of the voltage buffer 110 is coupled to the input 136 of the second source follower 130 and the second output 118 of the voltage buffer 110 is coupled to the output 138 of the second source follower 130.

The second input voltage Vin− at the second input 114 of the voltage buffer 110 is input to the input 136 of the second source follower 130. The second source follower 130 has a voltage gain of approximately one, in which a second output voltage Vout− at the output 138 of the second source follower 130 (which is coupled to the second output 118 of the voltage buffer 110) is approximately equal to the second input voltage Vin− minus the gate-to-source voltage Vgs2 of the second transistor 132. Thus, the second output voltage Vout− tracks the second input voltage Vin− where the second output voltage Vout− is shifted down from the second input voltage Vin− by Vgs2. When the second input voltage Vin− increases, the second source follower 130 sources current from the supply rail to the second load capacitor C_{L2} through the second transistor 132. The sourced current charges the second load capacitor C_{L2} which increases the second output voltage Vout− to track the increase in the second input voltage Vin−. When the second input voltage Vin− decreases, the second current source 134 sinks current from the second load capacitor C_{L2}. The sunk current discharges the second load capacitor C_{L2} which decreases the second output voltage Vout− to track the decrease in the second input voltage Vin−.

In this example, the bandwidth of the voltage buffer 110 is limited by the bias current I0 of the first current source 124 and the bias current I0 of the second current source 134. This is because the bias current I0 of the first current source 124 is the only current available to discharge the first capacitive load C_{L1} when the first input voltage Vin+ decreases, and the bias current I0 of the second current source 134 is the only current available to discharge the second capacitive load C_{L2} when the second input voltage Vin− decreases. The bandwidth of the voltage buffer 110 may be increased by increasing the bias current I0 of each of the current sources 124 and 134. However, increasing the bias current I0 of each of the current sources 124 and 134 increases the power consumption of the voltage buffer 110.

The voltage buffer 110 may also be implemented with one or more super source followers or one or more flipped source followers. A super source follower and a flipped source follower each employ a negative feedback loop to reduce output impedance and increase drivability. However, the bandwidth of the feedback loop may not be high enough for high-speed applications (e.g., frequencies in the gigahertz range). Also, the transistors in the feedback loop need to operate in the saturation region, which may limit operation headroom.

To address the above, aspects of the present disclosure provides a third current source and a differential pair of transistors in which the gate of one of the transistors is AC coupled to the input of the second source follower 130 and the gate of the other one of the transistors is AC coupled to the input of the first source follower 120. In certain aspects, the differential pair of transistors steer the current of the third current source to the first source follower 120 or the second source follower 130 based on the input voltages Vin+ and Vin− to provide additional current for bandwidth extension. The above features and other features of the present disclosure are discussed further below.

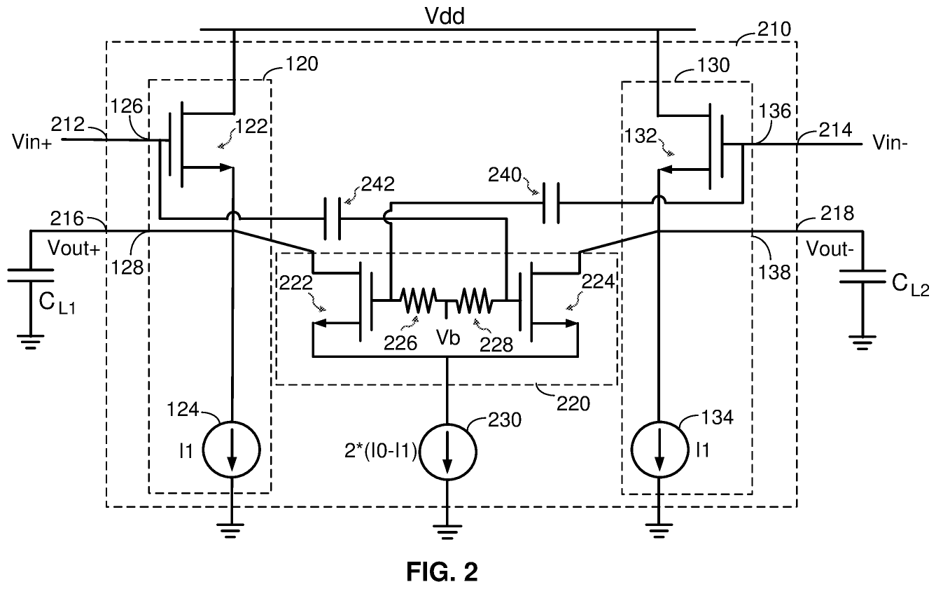

FIG. 2 shows an example of a voltage buffer 210 with bandwidth extension according to certain aspects. In this example, the voltage buffer 210 includes the first source follower 120 and the second source follower 130 discussed above with reference to FIG. 1. The voltage buffer 210 has a first input 212 and a second input 214, in which the first input 212 is coupled to the gate of the first transistor 122 and the second input 214 is coupled to the gate of the second transistor 132. The first input 212 and the second input 214 receive the first input voltage Vin+ and the second input voltage Vin−, respectively, discussed above. The voltage buffer 210 also includes a first output 216 and a second output 218, in which the first output 216 is coupled to the source of the first transistor 122 and the second output 218 is coupled to the source of the second transistor 132. The first output 216 and the second output 218 may drive the first and second capacitive loads C_{L1} and C_{L2}, respectively, discussed above.

In this example, the voltage buffer 210 also includes a differential pair 220 including a third transistor 222 and a fourth transistor 224. The voltage buffer 210 further includes a first coupling capacitor 240, a second coupling capacitor 242, and a third current source 230.

In this example, the drain of the third transistor 222 (e.g., an NFET) is coupled to the output 128 of the first source follower 120 (which is coupled to the source of the first transistor 122), and the first coupling capacitor 240 is coupled between the gate of the third transistor 222 and the input 136 of the second source follower 130 (which is coupled to the second input 214 of the voltage buffer 210). The first coupling capacitor 240 AC couples the second input 214 of the voltage buffer 210 to the gate of the third transistor 222. As a result, the gate of the third transistor 222 is driven by the second input voltage Vin− through the first coupling capacitor 240. The gate of the third transistor 222 is DC biased by a bias voltage Vb through a first resistor 226.

The drain of the fourth transistor 224 (e.g., an NFET) is coupled to the output 138 of the second source follower 130 (which is coupled to the source of the second transistor 132), and the second coupling capacitor 242 is coupled between the gate of the fourth transistor 224 and the input 126 of the first source follower 120 (which is coupled to the first input 212 of the voltage buffer 210). The second coupling capacitor 242 AC couples the first input 212 of the voltage buffer 210 to the gate of the fourth transistor 224. As a result, the gate of the fourth transistor 224 is driven by the first input voltage Vin+ through the second coupling capacitor 242. The gate of the fourth transistor 224 is DC biased by the bias voltage Vb through a second resistor 228.

The third current source 230 is coupled between the sources of the transistors 222 and 224 and ground. In this example, each of the first current source 124 and the second current source 134 is configured to provide bias current I1, where the bias current I1 may be less than the bias current I0 in FIG. 1. Also, in this example, the third current source 230 is configured to provide bias current 2*(I0−I1). In this example, the total current of the current sources 124, 134, and 230 is 2*I0 (i.e., I1+I1+2*(I0−I1)=2*I0), which is the same as the total current of the current sources 124 and 134 in FIG. 1. Thus, in this example, the current consumption is the same. However, it is to be appreciated that the present disclosure is not limited to this example.

In operation, the transistors 222 and 224 steer the bias current 2*(I0−I1) of the third current source 230 to the first source follower 120 or the second source follower 130 depending on the input voltages Vin+ and Vin−. For example, when the first input voltage Vin+ goes low and the second input voltage Vin− goes high, the first source follower 120 sinks current from the first load capacitor C_{L1} to discharge the first load capacitor C_{L1} and decrease the first output voltage Vout+ at the first output 216. In addition, the second source follower 130 sources current to the second load capacitor C_{L2} from the supply rail to charge the second load capacitor C_{L2} and increase the second output voltage Vout− at the second output 218. In this case, the second input voltage Vin− (which goes high) strongly turns on the third transistor 222, which causes the third transistor 222 to steer the current of the third current source 230 to the first source follower 120. As a result, the third current source 230 provides additional sink current for discharging the first load capacitor C_{L1}. The additional sink current causes the first output voltage Vin+ to decrease at a faster rate, which extends the bandwidth of the voltage buffer 210.

When the first input voltage Vin+ goes high and the second input voltage Vin− goes low, the second source follower 130 sinks current from the second load capacitor C12 to discharge the second load capacitor C_{L2} and decrease the second output voltage Vout− at the second output 218. In addition, the first source follower 120 sources current to the first load capacitor C_{L1} from the supply rail to charge the first load capacitor C_{L1} and increase the first output voltage Vout+ at the first output 216. In this case, the first input voltage Vin+ (which goes high) strongly turns on the fourth transistor 224, which causes the fourth transistor 224 to steer the current of the third current source 230 to the second source follower 130. As a result, the third current source 230 provides additional sink current for discharging the second load capacitor C_{L2}. The additional sink current causes the second output voltage Vin− to decrease at a faster rate, which extends the bandwidth of the voltage buffer 210.

Thus, the transistors 222 and 224 steer the bias current of the third current source 420 to the source follower 120 or 130 that is being driven low at a given time to provide the source follower with additional sink current. Since the source followers 120 and 130 are driven by a differential signal, one of the source followers 120 and 130 is driven low at a time. Thus, the additional sink current provided by the third current source 420 is needed by one of the source followers 120 and 130 at a time.

The transistors 222 and 224 and the third current source 230 significantly boost the sink current for the source follower 120 or 130 that is being driven low at a given time. For example, when the current I1 of each of the current sources 124 and 134 is equal to 0.5*I0, the current 2*(I0−I1) of the third current source is equal to I0 and the total sink current available to the source follower 120 or 130 that is being driven low is 1.5*I0 instead of I0 in FIG. 1. As a result, the bandwidth is increased by a factor of 1.5× over the implementation shown in FIG. 1 while the total current consumption is the same (i.e., 2*I0 in this example). In other words, the transistors 222 and 224 and the third current source 230 extend the bandwidth of the voltage buffer 210 without a power penalty in this example.

Unlike a super source follower and a flipped source follower which use feedback, the voltage buffer 210 uses feedforward to achieve bandwidth extension, in which the input voltages Vin− and Vin+ are fed to the gates of the transistors 222 and 224, respectively, through the coupling capacitors 240 and 242, respectively. The feedforward paths from the inputs 114 and 112 to the gates of the transistors 222 and 224, respectively, are faster than the feedback loops of the super source follower and the flipped source follower, allowing the voltage buffer 210 to achieve a wider bandwidth.

In addition, the currents of the current sources 124, 134, and 230 are approximately constant and insensitive to changes in the input signals (e.g., Vin+ and Vin) at the inputs 112 and 114 of the voltage buffer 210. This allows the voltage buffer 210 to achieve good linearity over a large input voltage swing.

The voltage buffer 210 is also suitable for low voltage supply design since only the output nodes (i.e., the outputs 216 and 218) have large voltage swing in this example.

Also, the transistors 222 and 224 do not interfere with the DC gain of the source followers 120 and 130. This is because the coupling capacitors 240 and 242 act as open circuits at low frequencies. As a result, the voltage buffer 210 behaves as the voltage buffer 110 at low frequencies.

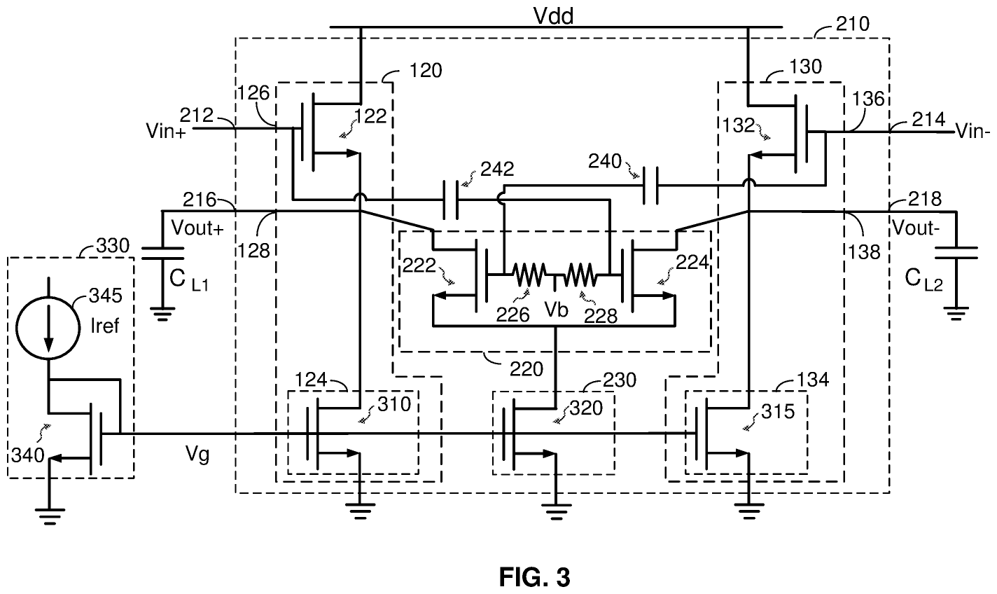

FIG. 3 shows an exemplary implementation of the current sources 124, 134, and 230 according to certain aspects. In this example, the first current source 124 includes a fifth transistor 310 (e.g., an NFET), in which the drain of the fifth transistor 310 is coupled to the source of the first transistor 122 and the source of the fifth transistor 310 is coupled to ground. The second current source 134 includes a sixth transistor 315 (e.g., an NFET), in which the drain of the sixth transistor 315 is coupled to the source of the second transistor 132 and the source of the sixth transistor 315 is coupled to ground. The third current source 230 includes a seventh transistor 320, in which the drain of the seventh transistor 320 is coupled to the sources of the third and fourth transistors 222 and 224, and the source of the seventh transistor 320 is coupled to ground. It is to be appreciated that each of the transistors 310, 315, and 320 may be implemented with two or more transistors coupled in parallel in some implementations.

In this example, a gate bias circuit 330 is coupled to the gates of the transistors 310, 315, and 320. As discussed further below, the gate bias circuit 330 biases the gates of the transistors 310, 315, and 320 with a gate bias voltage vg to set the currents of the current sources 124, 134, and 230 based on a reference current Iref.

In the example in FIG. 3, the gate bias circuit 330 includes an eighth transistor 340 and a reference current source 345 configured to generate the reference current Iref. The reference current source 345 is coupled to the drain of the eighth transistor 340. The gate of the eighth transistor 340 is coupled to the drain of the eighth transistor 340. The gate of the eighth transistor 340 is also coupled to the gates of the transistors 310, 315, and 320.

In operation, the reference current Iref from the reference current source 345 flows through the eighth transistor 340. The reference current Iref flowing through the eighth transistor 340 produces the gate bias voltage vg at the gate of the eighth transistor 340. The gate bias voltage vg biases the gate of the fifth transistor 310 such that the fifth transistor 310 provides a current that is approximately equal to the reference current Iref multiplied by a proportionality factor of n. The proportionality factor n may be approximately equal to a ratio of a channel width of the fifth transistor 310 over a channel width of the eighth transistor 340. The proportionality factor n may be equal to one or greater than one.

The gate bias voltage vg also biases the gate of the sixth transistor 315 such that the sixth transistor 315 provides a current that is approximately equal to the reference current Iref multiplied by the proportionality factor of n. In this example, the fifth transistor 310 and the sixth transistor 315 may have approximately the same channel width so that the bias currents of the first current source 124 and the second current source 134 are approximately the same.

The gate bias voltage vg also biases the gate of the seventh transistor 320 such that the seventh transistor 320 provides a current that is approximately equal to the reference current Iref multiplied by a proportionality factor of m. The proportionality factor m may be approximately equal to a ratio of a channel width of the seventh transistor 320 over the channel width of the eighth transistor 340. The proportionality factor m may be the same or different from the proportionality factor n. For example, to make the current of the third current source 230 approximately twice the current of each of the current sources 124 and 134, the proportionality factor m may be made equal to two times the proportionality factor of n (e.g., the channel width of the seventh transistor 320 may be made twice as wide as the channel width of each of the transistors 310 and 315).

Thus, in this example, the current sources 124, 134, and 230 may be set to desired currents by setting the reference current Iref and the proportionality factors m and n accordingly.

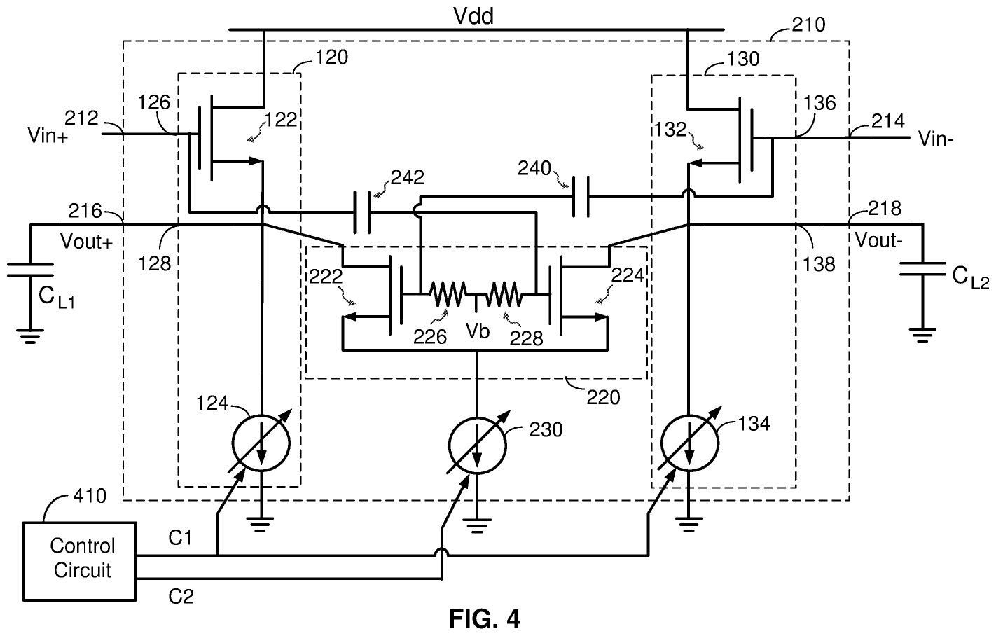

In certain aspects, the current sources 124, 134, and 230 may be implemented with programmable current sources that allow the currents of the current sources 124, 134, and 230 to be reconfigurable. In this regard, FIG. 4 shows an example in which each of the current sources 124, 134, and 230 is implemented with a respective programmable current source (indicated by the diagonal arrows in FIG. 4). As used herein, a “programmable current source” is a current source that can be programmed (i.e., set) to different currents based on a control signal. A programmable current source may also be referred as an adjustable current source, a variable current source, a tunable current source, or another term.

In this example, each of the first and second current sources 124 and 134 may be programmed (e.g., digitally programmed) to any current in a first set currents based on a first control signal C1 from a control circuit 410. The first control signal C1 may be a digital control signal (e.g., a thermometer code) indicating one of the currents in the first set of currents. In this example, each of the current sources 124 and 134 is configured to set its current to the current indicated by the first control signal C1. In some implementations, the first control signal C1 may also be used to selectively turn off (e.g., disable) the current sources 124 and 134.

In this example, the third current source may be programmed (e.g., digitally programmed) to any current in a second set currents based on a second control signal C2 from the control circuit 410. The second control signal C2 may be a digital control signal (e.g., a thermometer code) indicating one of the currents in the second set of currents. In this example, the third current source 230 is configured to set its current to the current indicated by the second control signal C2. In some implementations, the second control signal C2 may also be used to selectively turn off (e.g., disable) the third current source 230.

In this example, the control circuit 410 may be configured to set the currents of the current sources 124, 134, and 230 using the control signals C1 and C2. For example, in some implementations, the control circuit 410 may be configured to set the currents of the current sources 124, 134, and 230 based on a frequency of the differential input signal input to the voltage buffer 210. For example, the control circuit 410 may turn off the third current source 230 when the frequency of the input signal is less than a threshold frequency. In this case, bandwidth extension may not be needed when the frequency of the input signal is less than the threshold frequency. The control circuit 410 may turn on the third current source 230 to provide bandwidth extension when the frequency of the input signal is greater than the threshold frequency. In another example, the control circuit 410 may increase the current of the third current source 230 and/or increase the currents of the current sources 124 and 134 for higher frequencies to extend the bandwidth for the higher frequencies.

It is to be appreciated that, in some implementations, the third current source 230 may be programable while the first and second current sources 124 and 134 are not programmable.

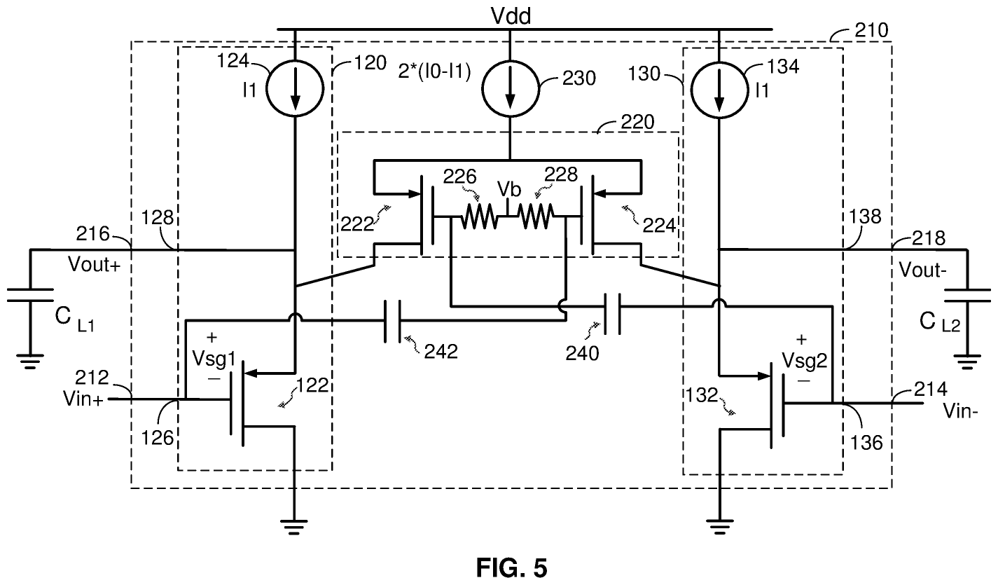

In the example shown in FIGS. 2 to 4, each of the transistors 122, 132, 222, and 224 is implemented with a respective NFET. However, it is to be appreciated that the transistors 122, 132, 222, and 224 are not limited to NFETs. In this regard, FIG. 5 shows an example in which each of the transistors 122, 132, 222, and 224 is implemented with a respective p-type field effect transistor (PFET). In the example in FIG. 5, the structure of the voltage buffer 210 is flipped vertically with respect to the example shown in FIG. 2.

In this example, the drain of the first transistor 122 and the drain of the second transistor 132 are coupled to ground. The first current source 124 is coupled between the supply rail and the source of the first transistor 122, the second current source 134 is coupled between the supply rail and the source of the second transistor 132, and the third current source 230 is coupled between the supply rail and the sources of the transistors 222 and 224.

In this example, the first output voltage Vout+ is shifted up from the first input voltage Vin+ by the source-to-gate voltage Vsg1 of the first transistor 122, and the second output voltage Vout− is shifted up from the second input voltage Vin− by the source-to-gate voltage Vsg2 of the second transistor 132. Also, in this example, the transistors 222 and 224 steer the current of the third current source 230 to the source follower 120 or 130 that is being driven high by the differential input signal at a given time. Thus, in this example, the transistors 222 and 224 and the third current source 230 extends the bandwidth of the voltage buffer 210 by providing additional source current to the source follower 120 or 130 that is being driven high at a given time.

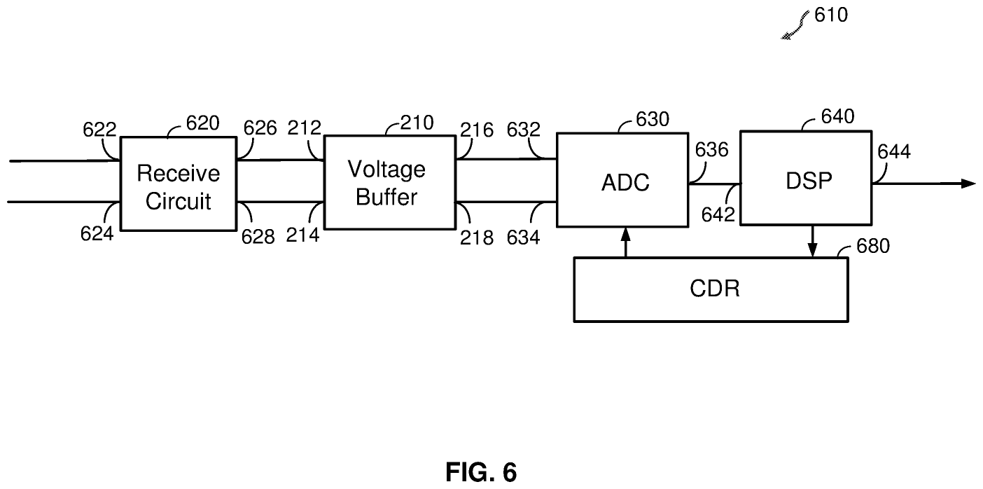

FIG. 6 shows an example of a system 610 in which the voltage buffer 210 may be used. However, it is to be appreciated that the voltage buffer 210 is not limited to the exemplary system 610, and that the voltage buffer 210 may be used in other systems.

In this example, the system 610 includes a receive circuit 620, the voltage buffer 210, an ADC 630, and a digital signal processor (DSP) 640. The receive circuit 620 is configured to receive a differential signal at first and second inputs 622 and 624, process the differential signal, and output the processed differential signal at first and second outputs 626 and 628. For example, the system 610 may be integrated on a chip and the differential signal come from another chip coupled to the chip via a differential channel. In this example, the processing performed by the receive circuit 620 may include one or more of the following: impedance matching with the channel, continuous time linear equalization to compensate for high frequency attenuation in the channel, amplification, and the like.

In this example, the first and second inputs 212 and 214 of the voltage buffer 210 are coupled to the first and second outputs 626 and 628, respectively, of the receive circuit 620, and the first and second outputs 216 and 218 of the voltage buffer 210 are coupled to first and second inputs of the ADC 630. The voltage buffer 210 receives the differential signal from the receive circuit 620 at the first and second inputs 212 and 214, and drives the first and second inputs 632 and 634 of the ADC 630 based on the differential signal. In this example, the input capacitances of the ADC 630 correspond to the capacitive loads C_{L1} and C_{L2}. The ADC 630 converts the differential signal into a digital signal and outputs the digital signal to the DSP 640 via output 636.

The DSP 640 receives the digital signal from the ADC 630 via input 642 and processes the digital signal in the digital domain. The processing performed by the DSP 640 may include one or more of the following: decision feedback equalization (DFE) to compensate for intersymbol interference (ISI), feed-forward equalization (FFE), ADC calibration, and the like. The DSP 640 outputs the processed digital signal at the output 644. The output 644 may be coupled to a deserializer (not shown), another processor, or the like.

In this example, the system 610 also includes a clock data recovery (CDR) circuit 680 for extracting timing information from the DSP 640, generating a clock signal based on the timing information, and inputting the clock signal to the ADC 630 to time operations of the ADC 630 (e.g., time sample and hold operations in the ADC 630).

It is to be appreciated that the system 610 is not limited the example shown in FIG. 6. For example, the system 610 may include one or more additional components not shown in FIG. 6 and/or one or more of the components shown in the example in FIG. 6 may be omitted in some implementations.

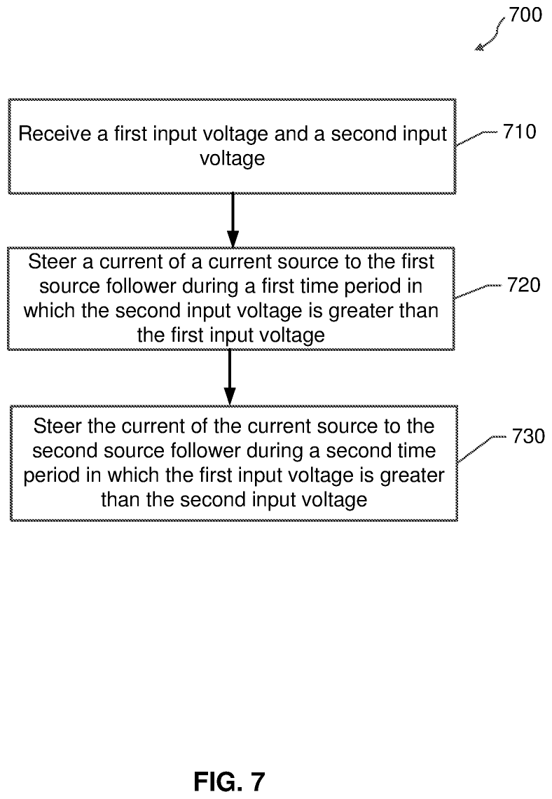

FIG. 7 illustrates a method 700 for operating a voltage buffer according to certain aspects. The voltage buffer (e.g., the voltage buffer 210) includes a first source follower (e.g., the first source follower 120) and a second source follower (e.g., the second source follower 130).

At block 710, a first input voltage and a second input voltage are received. For example, the first input voltage may correspond to the first input voltage Vin+ and the second input voltage may correspond to the second input voltage Vin−.

At block 720, a current of a current source is steered to the first source follower during a first time period in which the second input voltage is greater than the first input voltage. For example, the current source may correspond to the third current source 230, and the third transistor 222 may steer the current to the first source follower.

At block 730, the current of the current source is steered to the second source follower during a second time period in which the first input voltage is greater than the second input voltage. For example, the fourth transistor 224 may steer the current to the second source follower.

The method 700 may also include driving an input of the first source follower with the first input voltage, and driving an input of the second source follower with the second input voltage. For example, the input of the first source follower may correspond to the input 126 of the first source follower 120, and the input of the second source follower may correspond to the input 136 of the second source follower 130.

Implementation examples are described in the following numbered clauses:
1. A voltage buffer, comprising:
   a first transistor, wherein a gate of the first transistor is coupled to a first input of the voltage buffer, and a source of the first transistor is coupled to a first output of the voltage buffer;
   a first current source coupled to the source of the first transistor;
   a second transistor, wherein a gate of the second transistor is coupled to a second input of the voltage buffer, and a source of the second transistor is coupled to a second output of the voltage buffer;
   a second current source coupled to the source of the second transistor;
   a third transistor, wherein a drain of the third transistor is coupled to the source of the first transistor;
   a first coupling capacitor coupled between a gate of the third transistor and the second input of the voltage buffer;
   a fourth transistor, wherein a drain of the fourth transistor is coupled to the source of the second transistor;
   a second coupling capacitor coupled between a gate of the fourth transistor and the first input of the voltage buffer; and
   a third current source coupled to a source of the third transistor and a source of the fourth transistor.
2. The voltage buffer of clause 1, wherein:
   a drain of the first transistor and a drain of the second transistor are coupled to a supply rail;
   the first current source is coupled between the source of the first transistor and a ground;
   the second current source is coupled between the source of the second transistor and the ground;
   the third current source is coupled between the source of the third transistor and the ground; and
   the third current source is coupled between the source of the fourth transistor and the ground.
3. The voltage buffer of clause 2, wherein each of the first transistor, the second transistor, the third transistor, and the fourth transistor comprises a respective n-type field effect transistor (NFET).
4. The voltage buffer of clause 1, wherein:
   a drain of the first transistor and a drain of the second transistor are coupled to a ground;
   the first current source is coupled between the source of the first transistor and a supply rail;
   the second current source is coupled between the source of the second transistor and the supply rail;
   the third current source is coupled between the source of the third transistor and the supply rail; and
   the third current source is coupled between the source of the fourth transistor and the supply rail.
5. The voltage buffer of clause 4, wherein each of the first transistor, the second transistor, the third transistor, and the fourth transistor comprises a respective p-type field effect transistor (PFET).
6. The voltage buffer of any one of clauses 1 to 5, wherein the third current source comprises a programmable current source.
7. The voltage buffer of clause 6, wherein each of the first current source and the second current source comprises a respective programmable current source.
8. The voltage buffer of any one of clauses 1 to 7, wherein the first output of the voltage buffer is coupled to a first input of an analog-to-digital converter (ADC), and the second output of the voltage buffer is coupled to a second input of the ADC.
9. The voltage buffer of any one of clauses 1 to 8, wherein the first current source comprises a fifth transistor, the second current source comprises a sixth transistor, the third current source comprises a seventh transistor, and the voltage buffer further comprises a bias circuit configured to bias a gate of the fifth transistor, a gate of the sixth transistor, and a gate of the seventh transistor.
10. The voltage buffer of clause 9, wherein the bias circuit comprises:
   a reference current source; and
   an eighth transistor, wherein a drain of the eighth transistor is coupled to the reference current source, and a gate of the eighth transistor is coupled to the drain of the eighth transistor, the gate of the fifth transistor, the gate of the sixth transistor, and the gate of the seventh transistor.
11. A voltage buffer, comprising:
   a first source follower having an input and an output;
   a second source follower having an input and an output;
   a first transistor, wherein a drain of the first transistor is coupled to the output of the first source follower;
   a first coupling capacitor coupled between a gate of the first transistor and the input of the second source follower;
   a second transistor, wherein a drain of the second transistor is coupled to the output of the second source follower;
   a second coupling capacitor coupled between a gate of the second transistor and the input of the first source follower; and
   a current source coupled to a source of the first transistor and a source of the second transistor.
12. The voltage buffer of clause 11, wherein the current source comprises a programmable current source.
13. The voltage buffer of clause 11 or 12, wherein the output of the first source follower is coupled to a first input of an analog-to-digital converter (ADC), and the output of the second source follower is coupled to a second input of the ADC.
14. The voltage buffer of any one of clauses 11 to 13, wherein the current source comprises a third transistor, and the voltage buffer further comprises a bias circuit configured to bias the third transistor.
15. The voltage buffer of clause 14, wherein the bias circuit comprises:
   a reference current source; and
   a fourth transistor, wherein a drain of the fourth transistor is coupled to the reference current source, and a gate of the fourth transistor is coupled to the drain of the fourth transistor and the gate of the third transistor.
16. A method for operating a voltage buffer, wherein the voltage buffer includes a first source follower and a second source follower, the method comprising:
   receiving a first input voltage and a second input voltage;
   steering a current of a current source to the first source follower during a first time period in which the second input voltage is greater than the first input voltage; and
   steering the current of the current source to the second source follower during a second time period in which the first input voltage is greater than the second input voltage.
17. The method of clause 16, further comprising:
   driving an input of the first source follower with the first input voltage; and
   driving an input of the second source follower with the second input voltage.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect electrical coupling between two structures. It is also to be appreciated that the term “ground” may refer to a DC ground or an AC ground, and thus the term “ground” covers both possibilities. As used herein, “approximately” means within 90 percent to 110 percent of the stated value.

Any reference to an element herein using a designation such as “first,” “second,” and so forth does not generally limit the quantity or order of those elements. Rather, these designations are used herein as a convenient way of distinguishing between two or more elements or instances of an element. Thus, a reference to first and second elements does not mean that only two elements can be employed, or that the first element must precede the second element.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed is:

1. A voltage buffer, comprising:
a first transistor, wherein a gate of the first transistor is coupled to a first input of the voltage buffer, and a source of the first transistor is coupled to a first output of the voltage buffer;
a first current source coupled to the source of the first transistor;
a second transistor, wherein a gate of the second transistor is coupled to a second input of the voltage buffer, and a source of the second transistor is coupled to a second output of the voltage buffer;
a second current source coupled to the source of the second transistor;
a third transistor, wherein a drain of the third transistor is coupled to the source of the first transistor;
a first coupling capacitor coupled between a gate of the third transistor and the second input of the voltage buffer;
a fourth transistor, wherein a drain of the fourth transistor is coupled to the source of the second transistor;
a second coupling capacitor coupled between a gate of the fourth transistor and the first input of the voltage buffer; and
a third current source coupled to a source of the third transistor and a source of the fourth transistor.

2. The voltage buffer of claim 1, wherein:
a drain of the first transistor and a drain of the second transistor are coupled to a supply rail;
the first current source is coupled between the source of the first transistor and a ground;
the second current source is coupled between the source of the second transistor and the ground;
the third current source is coupled between the source of the third transistor and the ground; and
the third current source is coupled between the source of the fourth transistor and the ground.

3. The voltage buffer of claim 2, wherein each of the first transistor, the second transistor, the third transistor, and the fourth transistor comprises a respective n-type field effect transistor (NFET).

4. The voltage buffer of claim 1, wherein:
a drain of the first transistor and a drain of the second transistor are coupled to a ground;
the first current source is coupled between the source of the first transistor and a supply rail;
the second current source is coupled between the source of the second transistor and the supply rail;
the third current source is coupled between the source of the third transistor and the supply rail; and
the third current source is coupled between the source of the fourth transistor and the supply rail.

5. The voltage buffer of claim 4, wherein each of the first transistor, the second transistor, the third transistor, and the fourth transistor comprises a respective p-type field effect transistor (PFET).

6. The voltage buffer of claim 1, wherein the third current source comprises a programmable current source.

7. The voltage buffer of claim 6, wherein each of the first current source and the second current source comprises a respective programmable current source.

8. The voltage buffer of claim 1, wherein the first output of the voltage buffer is coupled to a first input of an analog-to-digital converter (ADC), and the second output of the voltage buffer is coupled to a second input of the ADC.

9. The voltage buffer of claim 1, wherein the first current source comprises a fifth transistor, the second current source comprises a sixth transistor, the third current source comprises a seventh transistor, and the voltage buffer further comprises a bias circuit configured to bias a gate of the fifth transistor, a gate of the sixth transistor, and a gate of the seventh transistor.

10. The voltage buffer of claim 9, wherein the bias circuit comprises:
a reference current source; and
an eighth transistor, wherein a drain of the eighth transistor is coupled to the reference current source, and a gate of the eighth transistor is coupled to the drain of the eighth transistor, the gate of the fifth transistor, the gate of the sixth transistor, and the gate of the seventh transistor.

11. A voltage buffer, comprising:
a first source follower having an input and an output;
a second source follower having an input and an output;
a first transistor, wherein a drain of the first transistor is coupled to the output of the first source follower;
a first coupling capacitor coupled between a gate of the first transistor and the input of the second source follower;
a second transistor, wherein a drain of the second transistor is coupled to the output of the second source follower;
a second coupling capacitor coupled between a gate of the second transistor and the input of the first source follower; and
a current source coupled to a source of the first transistor and a source of the second transistor.

12. The voltage buffer of claim 11, wherein the current source comprises a programmable current source.

13. The voltage buffer of claim 11, wherein the output of the first source follower is coupled to a first input of an analog-to-digital converter (ADC), and the output of the second source follower is coupled to a second input of the ADC.

14. The voltage buffer of claim 11, wherein the current source comprises a third transistor, and the voltage buffer further comprises a bias circuit configured to bias the third transistor.

15. The voltage buffer of claim 14, wherein the bias circuit comprises:
a reference current source; and
a fourth transistor, wherein a drain of the fourth transistor is coupled to the reference current source, and a gate of the fourth transistor is coupled to the drain of the fourth transistor and the gate of the third transistor.

16. A method for operating a voltage buffer, wherein the voltage buffer includes a first source follower and a second source follower, the method comprising:
receiving a first input voltage and a second input voltage;
steering a current of a current source to the first source follower during a first time period in which the second input voltage is greater than the first input voltage; and
steering the current of the current source to the second source follower during a second time period in which the first input voltage is greater than the second input voltage.

17. The method of claim 16, further comprising:
driving an input of the first source follower with the first input voltage; and
driving an input of the second source follower with the second input voltage.
